(19) United States
(12) Patent Application Publication
(10) Pub. No.: US 2010/0000602 A1
(43) Pub. Date: Jan. 7, 2010

(54) Photovoltaic Cell with Efficient Finger and Tab Layout

(75) Inventors: Kevin J. Gray, Nashua, NH (US); Chistopher E. Dubé, Lexington, MA (US); Michael A. Ralli, Holden, MA (US); Thomas S. LaMotte, Brookfield, MA (US); Stephen Fox, Leicester, MA (US)

Correspondence Address: Sunstein Kann Murphy & Timbers LLP, 125 SUMMER STREET, BOSTON, MA, 02110-1618, US

(73) Assignee: EVERGREEN SOLAR, INC., Marlborough, MA (US)

(21) Appl. No.: 12/511,557

(22) Filed: Jul. 29, 2009

Related U.S. Application Data
(63) Continuation-in-part of application No. 12/331,586, filed on Dec. 10, 2008.
(60) Provisional application No. 61/012,795, filed on Dec. 11, 2007.
(60) Provisional application No. 61/046,045, filed on Apr. 18, 2008.
(60) Provisional application No. 61/079,178, filed on Jul. 9, 2008.

(51) Int. Cl. H01L 31/02; H01L 31/18

(52) U.S. Cl. 136/256; 438/98; 257/E21.158

(57) ABSTRACT

A photovoltaic cell has a photosensitive substrate, a plurality of fingers in ohmic contact with the substrate, and a plurality of pads on the substrate. The plurality of pads effectively form a plurality of discontinuous busbars. Two of the fingers extend from a first pad of the plurality of pads. Specifically, a given one of the two fingers (“given finger”) may connect with a second pad of the plurality of pads. This given finger may have an inter-pad portion between the first and second pads. The cell further has a tab at least partially covering the inter-pad portion of the given finger.

### PRIORITY

This patent application is a continuation-in-part of U.S. patent application Ser. No. 12/331,586, filed Dec. 10, 2008, entitled, “PHOTOVOLATIC PANEL AND CELL WITH FINE FINGERS AND METHOD OF MANUFACTURE OF THE SAME,” assigned attorney docket number 3253/181, and naming Brown Williams, Christopher E. Dube, Stephen Fox, Andrew Gabor, and Michael A. Ralli as joint inventors, the disclosure of which is incorporated herein, in its entirety, by reference.

U.S. patent application Ser. No. 12/331,586 claims priority from the following provisional patent applications:

Application No. 61/012,795, filed Dec. 11, 2007 entitled, “PHOTOVOLTAIC CELL WITH FINE FINGERS AND METHOD OF MANUFACTURE OF THE SAME,” assigned attorney docket number 3253/135, and naming Brown Williams, Christopher E. Dube, and Andrew Gabor as joint inventors,

Application No. 61/046,045, filed Apr. 18, 2008 entitled, “PHOTOVOLTAIC CELL WITH TABS FOR REFLECTING LIGHT TOWARD SUBSTRATE,” assigned attorney docket number 3253/162, and naming Brown Williams as the sole inventor,

Application No. 61/079,178, filed Jul. 9, 2008, entitled, “EFFICIENT PHOTOVOLTAIC CELL,” assigned attorney docket number 3253/164, and naming Christopher E. Dube, Stephen Fox, Andrew Gabor, and Brown Williams as joint inventors.

The disclosures of these three provisional United States patent applications are incorporated herein, in their entireties, by reference.

### RELATED APPLICATIONS

This patent application also is related to the following United States patent application:

U.S. patent application Ser. No. 12/331,522, filed on Dec. 10, 2008, assigned attorney docket number 3253/182, naming Brown Williams as sole inventor, and entitled, “SHAPED TAB CONDUCTORS FOR A PHOTOVOLTAIC CELL,” the disclosure of which is incorporated herein, in its entirety, by reference.

### FIELD OF THE INVENTION

The invention generally relates to photovoltaic cells and modules/panels and, more particularly, the invention relates to improving efficiency of photovoltaic cells and modules/panels.

### BACKGROUND OF THE INVENTION

Photovoltaic cells convert light into electrical energy. To that end, a photovoltaic cell has a doped substrate that, when exposed to light, generates charge carriers, such as electrons. Conductors (referred to in the art as a “tabs”) coupled with the substrate conduct these electrons to another device, thus producing an electrical current.

One common photovoltaic cell technology collects the charge carriers by forming a plurality of conductive fingers on the substrate. The fingers conduct the collected charge carriers to the bonding site of one or more of the tabs to the substrate. These bonding sites, which are known in the art as “busbars,” provide a large surface for the tab to electrically connect with the fingers.

Problems arise when the physical connection between the tab and discontinuous busbars (i.e., busbars formed from a plurality of pads) inadvertently breaks. For example, in some designs, a solder weld normally secures the tab to the busbar pads. Undesirably, the connection to any one of those pads can be prone to some breakage, consequently reducing or eliminating that important electrical connection. In that case, charge carriers collected by the finger associated with that now disconnected pad can be lost, reducing cell efficiency.

### SUMMARY OF THE INVENTION

In accordance with one embodiment of the invention, a photovoltaic cell has a photosensitive substrate, a plurality of fingers in ohmic contact with the substrate, and a plurality of pads on the substrate. The plurality of pads effectively form a plurality of discontinuous busbars—sometimes simply referred to herein (e.g., in this Summary and in the Claims) as “busbars.” Two of the fingers extend from a first pad of the plurality of pads. Specifically, a given one of the two fingers (“given finger”) may connect with a second pad in the same busbar. This given finger may have an inter-pad portion between the first and second pads. The cell further has a tab at least partially covering the inter-pad portion of the given finger.

The two fingers may include a first finger that is generally orthogonal to the given finger. The first finger also may connect to a third pad so that the portion of the first finger that is external to the pads (i.e., between the pads) is uncovered (by tabs).

In some embodiments, the tab substantially entirely covers the inter-pad portion of the given finger. The fingers may include any of a variety of types, including continuous and/or discontinuous fingers. In other embodiments, the given finger connects with more pads. For example, the given finger may connect with a third pad, and the tab may cover at least a part of the given finger adjacent to the third pad.

As another example, the plurality of pads are arranged in a two dimensional array. The first pad and second pad are part of a specific busbar having a plurality of additional pads. The given finger electrically connects with the additional pads in the specific busbar. Further, the two-dimensional array may form a plurality of additional busbars that are generally parallel with the specific busbar. The cell also may include a plurality of additional tabs. Each additional busbar is connected to one of the additional tabs. In a manner similar to the specific busbar, each additional busbar may have multiple pads. Each busbar connects with at least one additional finger for connecting at least two of its own multiple pads.

In some embodiments, the plurality of pads may include pads that each have at least four concavities. Moreover, the noted two fingers, which may have substantially the same thicknesses or different thicknesses, illustratively can be not parallel.

In accordance with another embodiment of the invention, a method of forming a photovoltaic apparatus provides a photosensitive substrate, and forms a plurality of pads and first set of fingers on the substrate. The plurality of pads form a plurality of discontinuous busbars. The method also forms a given set of fingers. Each given finger physically and electrically connects with two of the pads; both of the (two) pads are also connected with at least one first finger. The method secures a plurality of tabs to the plurality of busbars so that each busbar is secured to a tab. Each tab covers at least a portion of the given fingers between pads.

In accordance with other embodiments of the invention, a photovoltaic cell has a photosensitive substrate with a top surface, a plurality of pads (forming a plurality of discontinuous busbars) on the top surface of the substrate, and a plurality of fingers in ohmic contact with the top surface of the substrate. The cell also has a plurality of tabs secured to the pads. The plurality of tabs substantially entirely cover the plurality of fingers. Moreover, the top surface of the substrate is substantially free of uncovered fingers

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a photovoltaic panel using cells configured in accordance with illustrative embodiments of the invention.

FIG. 1B schematically shows a pair of photovoltaic cells configured in accordance with illustrative embodiments of the invention.

FIG. 2A schematically shows a bottom view of a photovoltaic cell configured in accordance with illustrative embodiments of the invention.

FIG. 2B schematically shows a top view of a photovoltaic cell configured in accordance with illustrative embodiments of the invention.

FIG. 3 schematically shows an enlarged view of fingers and busbars in the photovoltaic cell of FIG. 2.

FIG. 4A schematically shows a photovoltaic cell, with tabs removed, configured in accordance with illustrative embodiments of the invention.

FIG. 4B schematically shows a close-up view of a portion of the photovoltaic cell of FIG. 4A.

FIG. 5A schematically shows the photovoltaic cell of FIG. 4A with its tabs secured to busbars.

FIG. 5B schematically shows a close-up view of a portion of the photovoltaic cell of FIG. 5B.

FIG. 6A schematically shows a photovoltaic cell with pad fingers between pairs of pads.

FIGS. 6B, 7, 8A and 8B respectively show close-up views of pad fingers connecting 2, 3, 4, and 6 pads.

FIG. 9 schematically shows a photovoltaic cell with pad fingers connecting different numbers of pads.

FIG. 10A schematically shows a photovoltaic cell implementing one embodiment of the invention with discontinuous fingers.

FIGS. 10B and 10C schematically show close-up views of the embodiment of FIG. 10A, but with pad fingers connecting two and three pads, respectively.

FIG. 11 shows a process of forming a photovoltaic cell in accordance with illustrative embodiments of the invention.

FIG. 12 schematically shows one embodiment of a pad configured in accordance with illustrative embodiments of the invention.

FIG. 13 schematically shows an embodiment of the invention with tabs substantially completely covering all fingers on the top face of the photovoltaic cell.

### DESCRIPTION OF ILLUSTRATIVE EMBODIMENTS

Bonds between a tab and busbar in a photovoltaic cell frequently break. It is a reality in the photovoltaic cell industry, and reduces cell efficiency. In illustrative embodiments, a photovoltaic cell with discontinuous busbars (i.e., busbars formed from pads) has conductive fingers configured to reduce carrier loss when the conductive bond between a tab and one or more of its pads breaks. To that end, such fingers interconnect some or all of the pads to one or more other pads in the same discontinuous busbar. Accordingly, if the tab bond breaks at a given pad, then carriers (e.g., electrons) for that pad can flow to another local pad. Consequently, those carriers are not completely lost, thus mitigating efficiency losses that could be caused by that bond break.

In other embodiments, the top face 14A of a photovoltaic cell has one type of fingers only; namely, fingers that are substantially completely covered by tabs. In other words, no finger on the top face 14A of the cell is exposed—all are substantially completely covered by tabs. This should reduce shading, permit thinner tabs and thus, improve cell efficiency. Details of illustrative embodiments are discussed below.

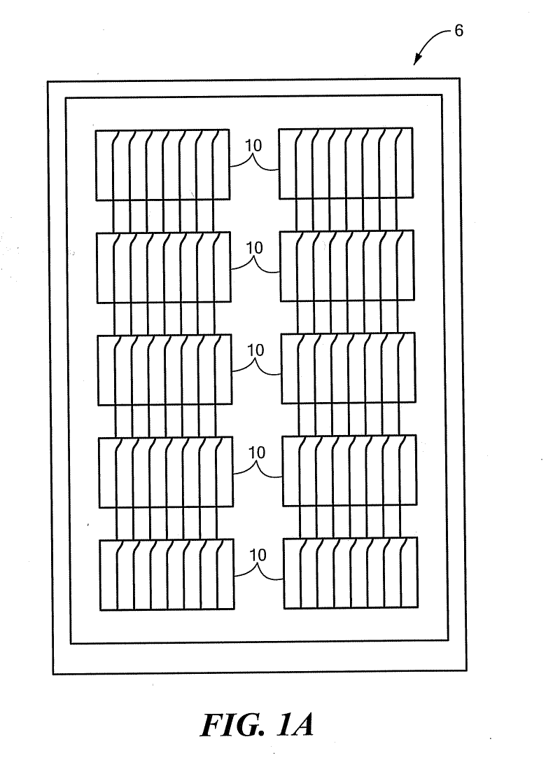

FIG. 1A schematically shows a photovoltaic module 6 (also known as a photovoltaic panel 6 or solar panel 6) that may incorporate photovoltaic cells 10 configured in accordance with illustrative embodiments of the invention. Among other things, the photovoltaic module 6 has a plurality of electrically interconnected photovoltaic cells 10 within a rigid frame. To protect the cells 10 and form the overall module structure, the module 6 also may have an encapsulating layer (not shown), a glass top layer (not shown), and a backskin (not shown, to provide back support). As discussed below, the individual cells 10 are electrically connected by a plurality of tabs 22, which FIG. 1 shows schematically only.

It should be reiterated that the module 6 shown in FIG. 1A serves merely as a schematic drawing of an actual module. Accordingly, the number of cells 10, the tab arrangement, and the cell topology can vary significantly within the context of the below description.

FIG. 1B schematically shows a photovoltaic cell 10 configured in accordance with illustrative embodiments of the invention and connected to a second photovoltaic cell 10A. As an example, these two cells 10 and 10A both may be within the module 6 of FIG. 1A. The two cells 10 and 10A may be configured in the same manner, or in a different manner. In the example shown, the first and second photovoltaic cells 10 and 10A are serially connected to combine their power.

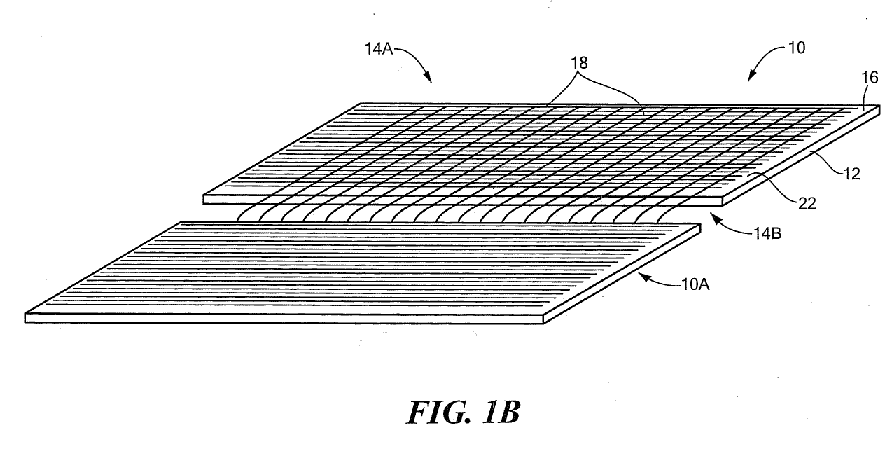

Among other things, the photovoltaic cell 10 has a doped substrate 12 with a plurality of conductors on its top and bottom faces/surfaces 14A and 14B to collect and transmit electricity/current to an external device, such as another photovoltaic cell 10 or an external load. More specifically, FIG. 2A schematically shows a bottom view of the photovoltaic cell 10, while FIG. 2B schematically shows a top view of the same photovoltaic cell 10.

Specifically, as shown in FIG. 2A, the bottom face 14B of the substrate 12 does not receive light and thus, may be completely covered by a conductive material to maximize its efficiency in collecting charge carriers. Accordingly, as shown in FIG. 2A, the bottom face 14B of the substrate 12 has a bottom surface metallic covering 26 (e.g., aluminum) with an exposed bottom contact 28 shaped to correspond with the shape of a metallic strip 24 (discussed below with respect to FIG. 2B) that electrically connects two cells 10. The photovoltaic cell 10 therefore serially connects with similar photovoltaic cells 10 by connecting their metallic strip 24 to its bottom contact 28, and/or by connecting its metallic strip 24 to their bottom contacts 28. Alternatively, the bottom contact 28 may be embodied by one or more small pads to which the strip 24 is electrically connected.

FIG. 2B shows the top face 14A, which has an antireflective coating (not explicitly shown in the figures) to capture more light incident light, and a pattern of deposited/integral conductive material to capture charge carriers and facilitate tab bonding. Specifically, among other things, the conductive material includes a plurality of thin fingers 18 traversing generally lengthwise (horizontally from the perspective of the figure) along the substrate 12, and a plurality of discontinuous busbars 20 traversing generally along the width (vertically from the perspective of the figures but partly covered by tabs 22, which are discussed below) of the substrate 12. As shown and discussed below, each discontinuous busbar 20 includes a plurality of regularly spaced pads 32 along its length. In the example shown, the discontinuous busbars 20 are generally arranged in a pattern that is more or less perpendicular to the fingers 18.

In various embodiments, the fingers 18 are much thinner than those known in the art. For example, some or all of the fingers 18 may have (average) thicknesses that are substantially less than about 120 microns. In fact, some embodiments have finger thicknesses of less than about 60 microns. Details of the finger thicknesses and related benefits are discussed more fully in the parent application (incorporated U.S. patent application Ser. No. 12/331,586). Other embodiments, however, do not require such thin fingers 18.

As shown in the various figures, the discontinuous busbars 20 are generally parallel to each other. In a similar manner, the horizontally oriented fingers 18 are generally parallel to each other. Alternative embodiments also may form the discontinuous busbars 20 and fingers 18 in different orientations. For example, the fingers 18, discontinuous busbars 20, or both could traverse in a random manner across the top face 14A of the substrate 12, at an angle to the fingers 18 and discontinuous busbars 20 shown, or in some other pattern as required by the application.

As noted above, the photovoltaic cell 10 also has a plurality of tab conductors 22 (referred to generally as “tabs 22” and shown in FIG. 2B, among other figures) electrically and physically connected to the discontinuous busbars 20/pads 32. Among other things, the tabs 22 may be formed from silver, silver plated copper wires, or silver plated copper wires to enhance conductivity. The tabs 22 transmit electrons gathered by the fingers 18 to the above noted metallic strip 24, which is connectable to either an external load or another photovoltaic cell 10 (e.g., as shown in FIG. 1).

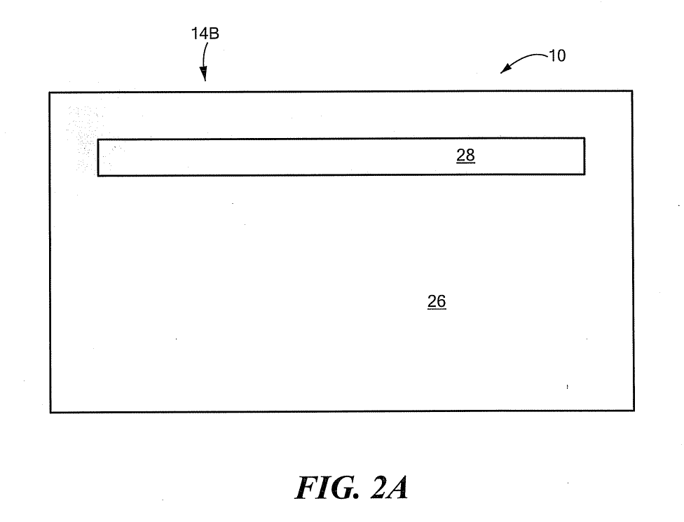

Conventional processes bond each tab 22 to a plurality of the busbar pads 32 making up a single discontinuous busbar 20. To that end, FIG. 3 schematically shows a close-up view of a tab 22A and its connection to the pads 32 and 32A of its discontinuous busbar 20. For example, solder may physically and electrically connect each tab 22 with its plurality of corresponding pads 32. Accordingly, only discrete portions of the tab 22 are secured to the substrate 12.

Additional fingers 18P, not shown in FIG. 2B or 3 because they are covered by the tabs 22, also are positioned beneath the tabs 22. In addition to performing the function of gathering charge carriers, these fingers 18P also beneficially aid efficiency if a tab/pad bond breaks (discussed in greater detail below).

More specifically, as noted above, these bond sites sometimes can break, thus eliminating the ohmic contact between the tab 22 and the bond pad 32. When this happens, certain prior art designs suffer from decreased efficiency. In particular, a tab 22 receives carriers from its finger 18 at the pads 32. When the tab/pad connection breaks, that finger 18 transmits the carriers to the next pad/discontinuous busbar along its path. Many such carriers do not survive long enough to be transmitted by that finger 18 due to transmission resistance.

More particularly, to compromise between shading/coverage and conductivity, many cell designers space the bond pads 32 on a single discontinuous busbar 20 closer together than the space between bond pads 32 of adjacent discontinuous busbars 20. FIG. 2B generally shows one example of such spacing. Accordingly, if the bond between a certain tab 22 and one of its bond pads 32 breaks, then carriers at that bond pad 32 must travel along the relevant finger 18 to one of the bond pads 32 of the adjacent discontinuous busbars 20.

To illustrate this phenomenon, FIG. 3 shows a given finger 18A that intersects two bond pads 32A and 32B of two different discontinuous busbars 20. A first tab 22A is bonded to the first pad 32A while a second tab 22B is bonded to second pad 32B. For the sake of discussion, assume that there are no fingers 18P underneath the tabs 22/22A, and the bond at pad 32A breaks. The tab 22A thus no longer electrically connects with the first pad 32A. Carriers collected in the vicinity around bond pad 32A thus cannot be transmitted along the intended tab 22A via the first pad 32A. Instead, those carriers now must travel along the finger 18A to an adjacent busbar pad 32, such as pad 32B. Traversing this relatively long resistive distance, however, may attenuate the carrier to the point where it no longer contributes to the current of the overall cell 10.

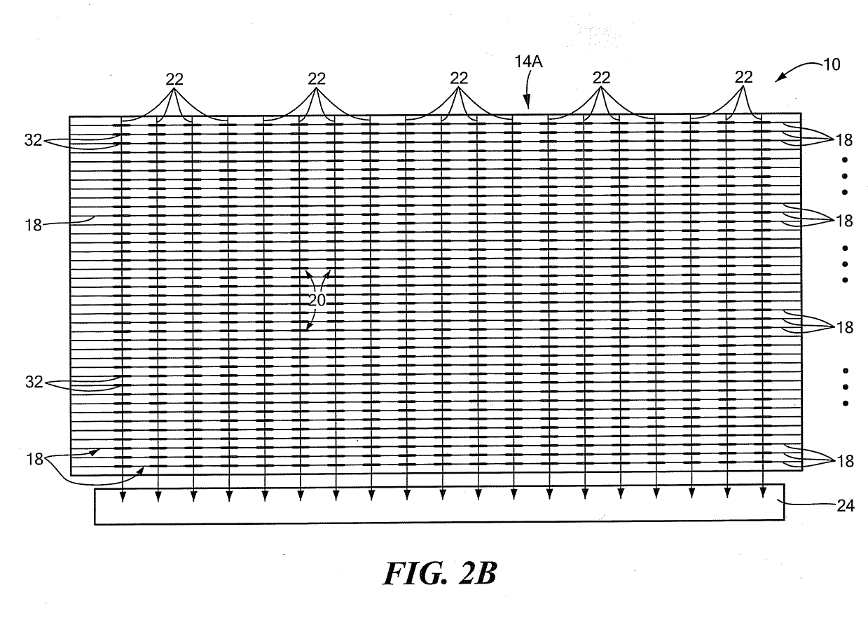

Illustrative embodiments of the invention compensate for this unintended but not unusual occurrence by positioning additional fingers 18P between the pads 32 of a single discontinuous busbar 20 (as noted above). Specifically, FIGS. 4A and 4B schematically show the top face 14A of a photovoltaic cell 10 (with its tabs 22 removed to better show the discontinuous busbars 20 and fingers 18 and 18P) having two sets of generally orthogonally oriented fingers 18 and 18P. Each finger 18 in the horizontal set (from the orientation of the drawings) collects charge carriers in a conventional manner as described, while each finger 18P in the vertical set connects the pads 32 in a single discontinuous busbar 20. As discussed below, the fingers 18P between pads in the same discontinuous busbar 20 also collects charge carriers. For convenience, the fingers 18P between pads on the same discontinuous busbar 20 also are referred to herein as “pad fingers 18P.”

The combination of pad fingers 18P and pads 32 is distinct from continuous busbars in a number of ways. In particular, the pad fingers 18P are not soldered to the tabs 22. Specifically, the substantial majority of the top facing area of a continuous busbar typically is soldered to a tab 22. For example, solder may reflow to the entire top face of a continuous busbar—as with a discontinuous busbar 20 (i.e., solder on the top faces of the pads only). This is in contrast to the pad fingers 18P, which are not soldered to the tabs 22. Indeed, in practice, some solder may inadvertently flow onto some parts of the pad fingers 18P, but that unintended consequence does not transform them into part of a continuous busbar. One of skill in the art should understand that distinction and thus, design cell fabrication processes to avoid soldering the tabs 22 to the pad fingers 18P.

In addition, continuous busbars have no pads 32. Instead, the pad fingers 18P are much thinner than the largest outer dimension of the pads 32. For example, the pad fingers 18P may have the same thickness as the other fingers 18 on the top face 14A of the cell 10, while the pads 32 may have outer dimensions that are much larger, such as two times, ten times, or fifty times larger. Other embodiments, however, vary the finger thicknesses of the two types of fingers 18 and 18P. In any event, the outer dimension of the pads 32 still are larger than the thickness of the pad fingers 18P. Various embodiments thus permit a designer to take advantage of the benefits of discontinuous busbars 20 while compensating for unintended breaks in the tab/pad bond.

Accordingly, if the bond between a given pad 32 and tab 22 breaks, then carriers merely traverse along the pad fingers 18P to the next adjacent pad 32 in a given discontinuous busbar 20. As noted above, this typically is a much shorter distance than the distance to another pad 32 on another discontinuous busbar 20. Accordingly, due to this disparity in the distance, the carrier may be able to contribute to the overall current of the photovoltaic cell 10.

The inventors took this unexpected approach despite teachings to the contrary. For example, among other things, the inventors understand that those in the art teach away from adding more conductive material to the substrate because it decreases efficiency in the substrate immediately beneath the conductive material. Such decreased efficiency impacts overall cell performance. Moreover, the additional conductive material adds further cost, which is contrary to the photovoltaic industry goal of grid parity. In addition, more conductive material generally shades more of the substrate 12, which prevents light from energizing the carriers on its surface. Consequently, those efficiency reductions, among other things (e.g., added fabrication complexity), teaches away from adding these fingers 18P.

After modeling and testing, however, the inventors nevertheless discovered that those efficiency reductions should be offset by efficiency improvements during real-world cell performance. Specifically, during actual use, it is anticipated that a certain number of tab bonds will break. Accordingly, assuming that such number of pad/tab bonds break, then these pad fingers 18P should improve efficiency. In any event, they represent a safeguard against anticipated breakage of the tab/pad bond.

It should be noted that orthogonal orientation of the pad fingers 18P and other fingers 18 is not necessary in various embodiments, such as those that have fingers 18 and/or 18P in alternative orientations (e.g., curved fingers, fingers at an angle to the longitudinal axis of the cell 10, etc . . . ). In fact, the pad fingers 18P and other fingers 18 can be non-linear and thus, extend outside of the direct line between the busbar pads 32. For example, the discontinuous busbars 20 and pad fingers 18P can be nonlinear, and, correspondingly, the tabs 22 can be non-linear. Illustrative embodiments orient the two different sets of fingers 18 and 18P in a non-parallel arrangement, such as that shown in the figures.

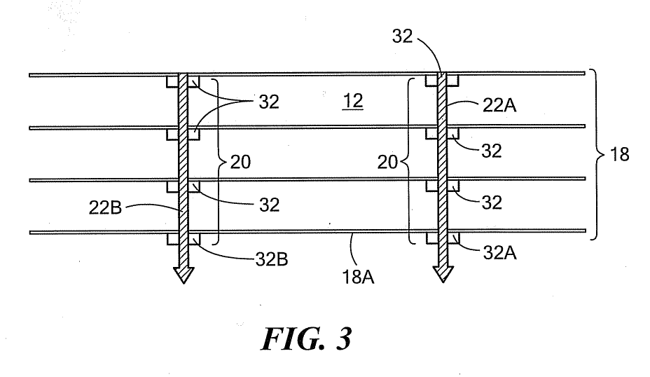

As noted, various embodiments extend the pad fingers 18P between each pad 32 in a given discontinuous busbar 20. This is clearly shown in FIG. 4A, which shows fifteen discontinuous busbars 20, fifteen corresponding pad fingers 18P, and thirty-five other fingers 18 that primarily gather charge carriers. FIGS. 5A and 5B schematically show the same cell 10 with its tabs 22 attached (FIG. 5B shows the enlarged view of a portion of FIG. 5A). As shown, each tab 22 substantially completely covers the pad fingers 18P of its corresponding discontinuous busbar 20. Accordingly, the pad fingers 18P effectively provide no additional shading. Some embodiments, however, may use thinner tabs 22 and thus, not substantially completely cover the pad fingers 18P.

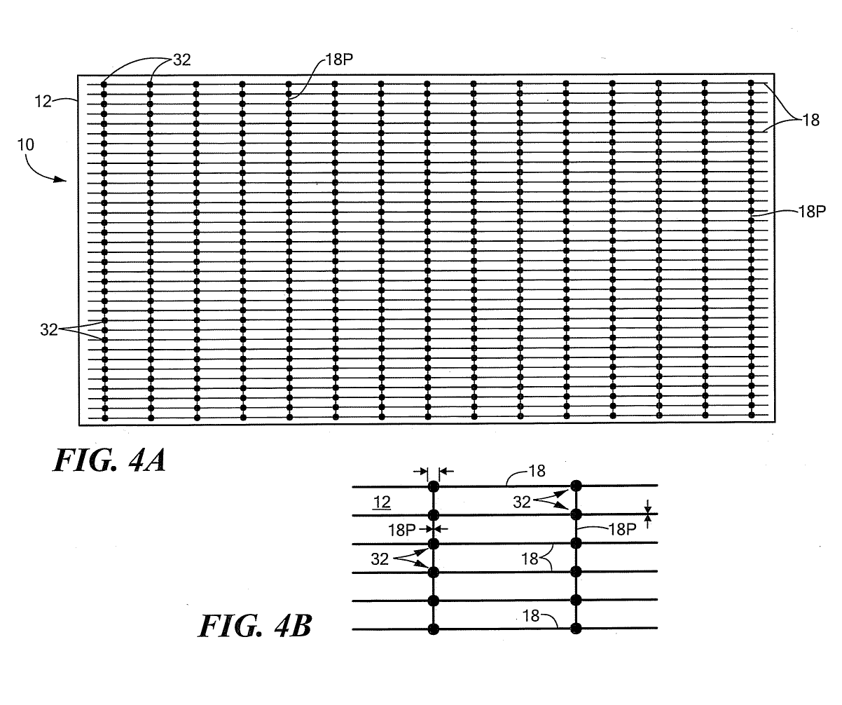

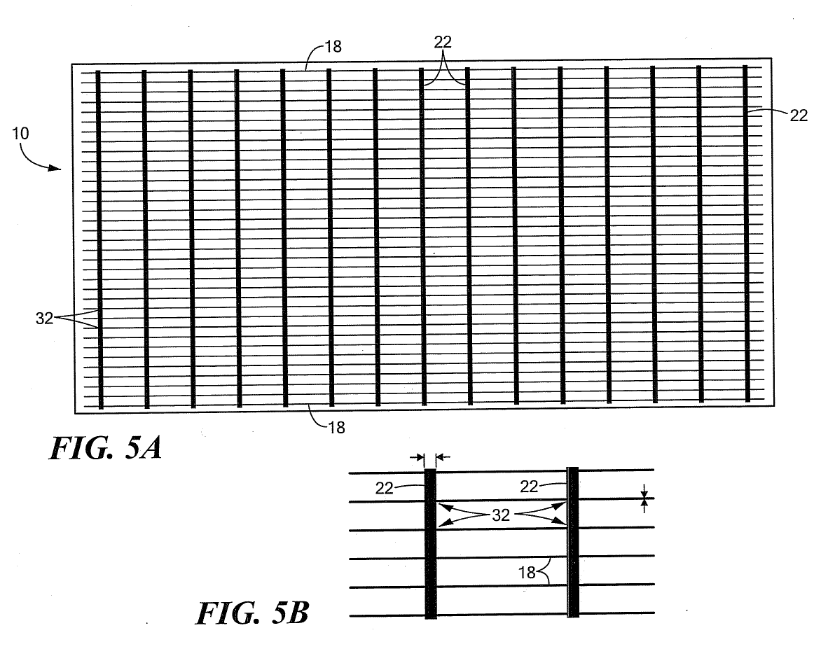

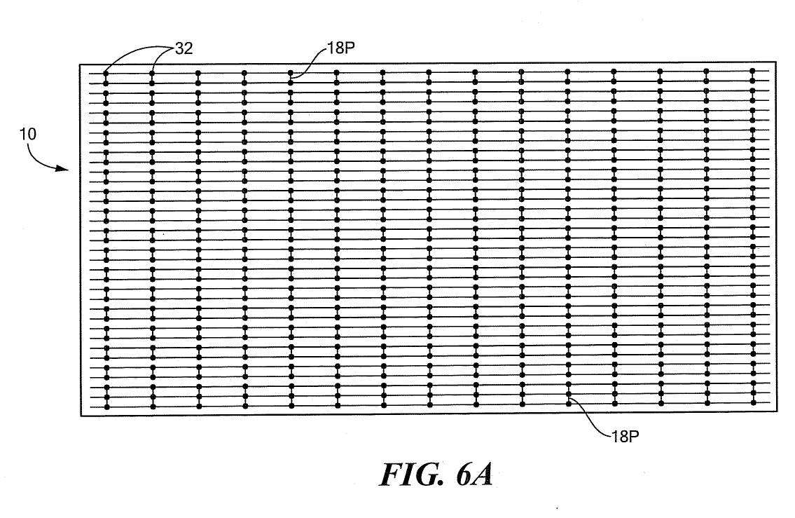

FIGS. 4A, 4B, 5A, and 5B merely show one of many different ways of using pad fingers 18P. Other embodiments may not use pad fingers 18P between all pads 32 in a given discontinuous busbar 20. For example, FIGS. 6A and 6B schematically show pad fingers 18P extending between two pads 32 only. In a corresponding manner, FIG. 7 schematically shows a close-up view of pad fingers 18P extending between groups of three pads 32. FIG. 8A schematically shows a close-up view of pad fingers 18P extending between groups of four pads 32, while FIG. 8B schematically shows a close-up view of pad fingers 18P between groups of six pads 32. These pad finger configurations are merely illustrative and not considered to limit various embodiments of the invention. Accordingly, a photovoltaic cell designer can design a given pad finger 18P so that it intermittently connects certain groups of pads 32 in a single discontinuous busbar 20, or all pads 32 in a single discontinuous busbar 20.

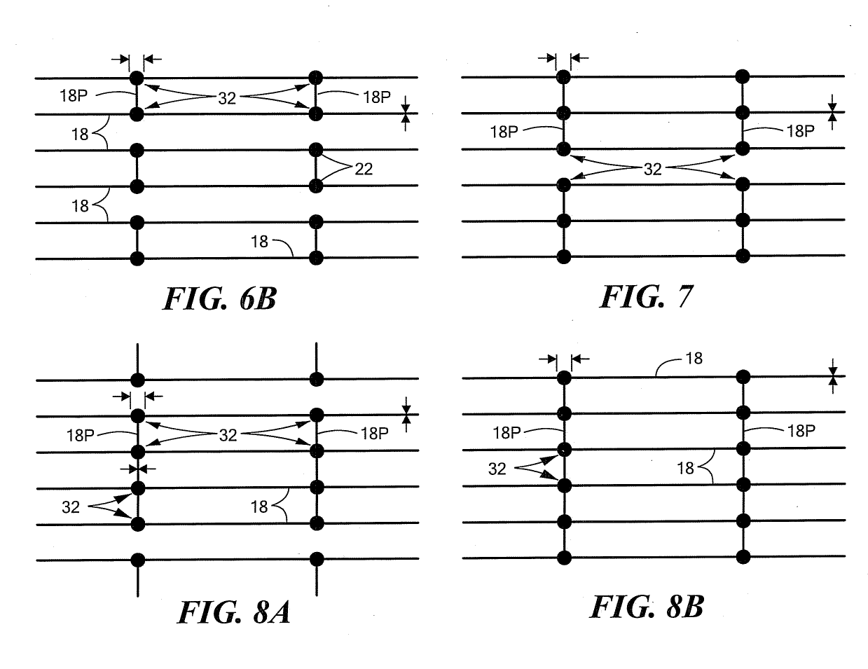

In fact, some cells 10 may have some discontinuous busbars 20 with pad fingers 18P, other discontinuous busbars 20 without pad fingers 18P, and other discontinuous busbars 20 with varying numbers and patterns of pad fingers 18P. FIG. 9 schematically shows one such embodiment, which also has discontinuous busbars 20 with pad fingers 18P in contact with varying numbers of pads 32. For example, one discontinuous busbar 20 has a pad finger configuration that alternatively connects two pads 32 only (as in FIG. 7A), while another discontinuous busbar 20 has a pad configuration that alternatively connects four pads 32. In fact, this figure also shows a single pad finger 18P alternatively connecting varying numbers of pads 32. Accordingly, a single cell 10 can have a wide variety of different combinations of pad fingers 18P. Although not shown, some embodiments can have one or more continuous busbars, which, of course, do not include pad fingers 18P since they have no pads 32.

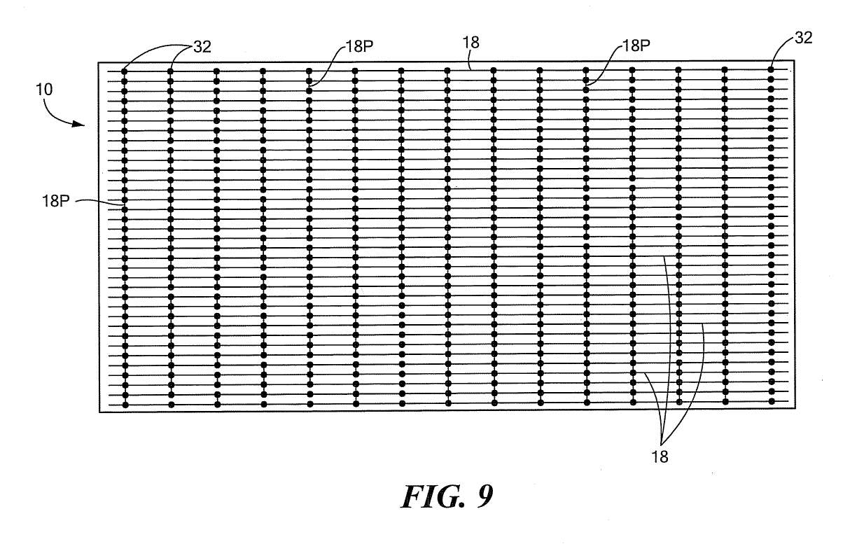

FIGS. 10A, 10B, and 10C show another embodiment using discontinuous fingers 18 for collecting charge carriers (with tabs removed, as in various other figures). FIGS. 10B and 10C are close-up views of a configuration similar to the discontinuous finger embodiment shown in FIG. 10A, but with different numbers of pads 32 connected by pad fingers 18P. Specifically, each (horizontal) finger 18 in this embodiment has a plurality of finger portions that each intersects a single discontinuous busbar 20. As known by those skilled in the art, an electron has a diffusion length; i.e., the length it can travel during its lifetime. That distance in certain embodiments is approximately 1 millimeter. The spacing between each finger portion of a given finger 18 (of the embodiment in FIGS. 10A and 10B) therefore preferably is no greater than about two diffusion lengths; namely, about 2 millimeters in this case. By way of example only, the spacing may be between about 0.5 and about 2 millimeters. Of course, the spacing may be less than about 0.5 millimeters or greater than 2 millimeters.

As shown more clearly in FIGS. 10B and 10C, the pads 32 shown in this embodiment are generally circular with diameter of about 0.4 millimeters. Each finger portion may have a length of about 7.8 millimeters and about a two millimeter spacing between the general centers of the pads 32 of a single discontinuous busbar 20. In a manner similar to other embodiments, the cell 10 of FIG. 10 has one or more of the discontinuous busbars 20 that each have a pad finger 18P connecting the two or more of its pads 32. Tabs 22 (not shown in FIGS. 10A-10C) thus may connect with the pads 32 as discussed above.

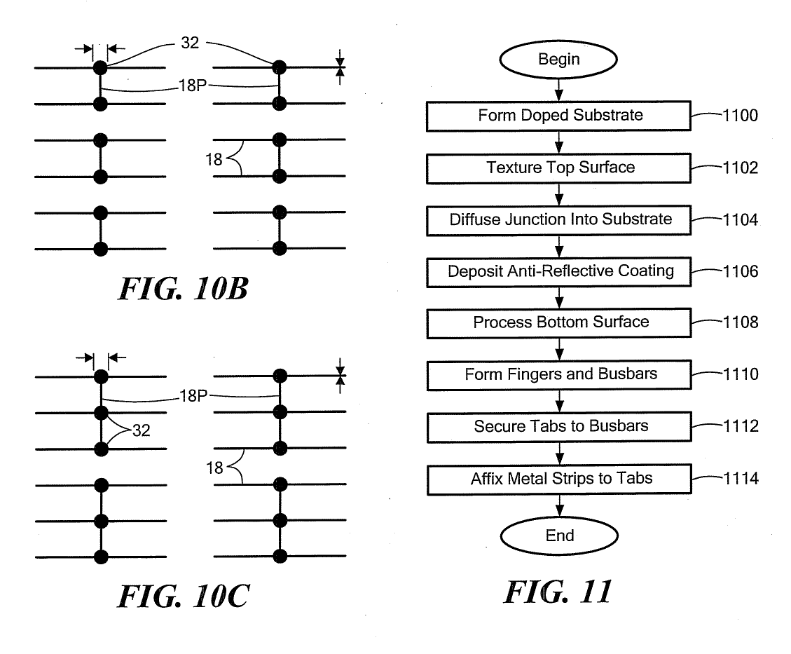

The circular pads 32 contrast the generally rectangular pads 32 of the embodiment shown in FIG. 3. In any event, alternative embodiments can have pads 32 with different shapes. The shapes may be selected based upon the application, the fabrication process, the tab size and shape, material, or other criteria. For example, the pads 32 may be irregularly shaped, diamond shaped, star shaped, etc . . . . In some cases, the pads 32 may have one or more concave surfaces, discussed in greater detail below (FIG. 12, discussed below).

To be clear, it should be noted that a finger 18 or 18P is comprised of various portions that extend between different pads 32. For example, in the case of a straight finger 18 (i.e., either continuous or discontinuous finger in which its segments are substantially co-planar), such as those shown in FIG. 3, finger 18A extends across both pads 32A and 32B. Such finger, however, is distinct from the other three fingers 18 horizontally above it.

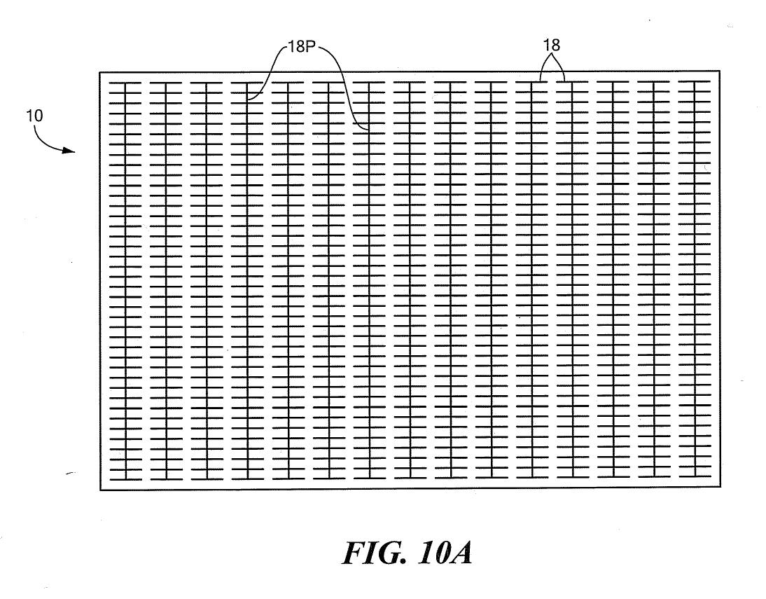

FIG. 11 shows a process for forming the photovoltaic cell 10 in accordance with illustrative embodiments of the invention. It should be noted that for simplicity, this described process is a significantly simplified version of an actual process used to form a photovoltaic cell 10. Accordingly, those skilled in the art would understand that the process may have additional steps not explicitly shown in FIG. 5. Moreover, some of the steps may be performed in a different order than that shown, or at substantially the same time. Those skilled in the art should be capable of modifying the process to suit their particular requirements.

The process begins at step 1100, which forms a doped substrate 12. To that end, the process may form any kind of doped substrate appropriate for the intended purposes. Illustrative embodiments form a p-type doped string ribbon wafer, such as those produced by Evergreen Solar, Inc. of Marlborough, Massachusetts. As known by those skilled in the art, string ribbon wafers typically are very thin, such as on the order of between about 150 and 300 microns.

After cleaning the surfaces 14A and 14B of the wafer/substrate 12, the process continues to step 1102 by texturing the top face 14A to reduce its shininess. This step should reduce reflections that could minimize the amount of light that excites charged carriers. To that end, conventional processes create a micro-texture on the top substrate surface 14A, giving it a “frosty” appearance.

Next, the process diffuses a junction into the substrate 12 (step 1104). Specifically, embodiments using a P-type string ribbon wafer may form a very thin layer of N-type material to the top face 14A of the substrate 12. For example, this layer may have a thickness of about 0.3 microns. Among other ways, the process may apply this layer by spraying a phosphorous compound onto the top face 14A of the wafer/substrate 12, and then heating the entire substrate 12 in a furnace. Of course, the junctions may be formed by other means and thus, the noted techniques are discussed for illustrative purposes only.

After removing the substrate 12 from the furnace, the process continues to step 1106 by depositing the above noted electrically insulating, antireflective coating to the top face 14A of the substrate 12. In a manner similar to the noted texture, one primary function of the antireflective coating is to increase the amount of light coupled into the photovoltaic cell 10. The antireflective coating may be formed from conventional materials, such as silicon nitride.

The process then continues to step 1108, which processes the bottom face 14B of the substrate 12. To that end, conventional screen-printing processes first form a bottom contact 28 from a silver paste on the substrate 12, and then mask the bottom contact 28 to form the bottom surface metallic covering 26 (e.g., formed from aluminum).

Simultaneously, before, or after processing the bottom surface 14B, the process begins processing the top face 14A by forming the arrays of fingers 18, 18P and discontinuous busbars 20 (step 1110). To that end, illustrative embodiments screen-print a highly conductive paste over a mask on the top face 14A of the substrate 12. The mask has the desired pattern for fingers 18, 18P and discontinuous busbars 20. Illustrative embodiments deposit one layer of conductive material only, although some embodiments can deposit multiple layers. To enhance conductivity, various embodiments use a silver paste to form the fingers 18, 18P, and discontinuous busbars 20.

In continuous finger embodiments, this step may deposit the fingers 18 as substantially continuous lines of the conductive material. Accordingly, fingers 18 formed this way should be free from breaks along their lengths. Despite these efforts, however, during or after processing, any of the fingers 18 may form one or more breaks along their lengths (referred to as “unintentional breaks”). Consequently, the resultant finger(s) 18 in turn often have one or more irregularly spaced breaks. Such breaks also may have irregular shapes.

Fingers 18 formed by processes to have no breaks thus are considered not to be discontinuous even if they have one or more such breaks. In a corresponding manner, fingers 18 engineered with spaces/discontinuities/breaks along their length, whether they are regularly or irregularly spaced, are considered to be discontinuous. The same discontinuous and continuous requirements also apply to discontinuous busbars 20, i.e., a continuous busbar with a non-engineered break is not a discontinuous busbar 20.

Some embodiments do not explicitly form the pads 32. Instead, such embodiments may simply form the pad fingers 18P and intersecting other fingers 18. Specifically, the mask/screen simply has the pattern of intersecting fingers 18 and 18P, such as those shown in the figures having orthogonal fingers 18 and 18P. Removal of the mask causes the material at the intersection to migrate to some extent, thus forming some pattern, such as that shown in FIG. 12. Specifically, this figure shows rounded concavities/arcs between the pad fingers 18P and other fingers 18. Accordingly, the mask forming those pads 32 did not have this pad pattern, but the pattern formed from the properties of the conductive material (e.g., silver paste).

It should be noted that discussion of screen-printing is for illustrative purposes only. Some or all of the various discussed components can be applied using other technologies. Among other technologies, such embodiments may use inkjet printing or aerojet printing.

After screen-printing both surfaces 14A and 14B, the process passes the substrate 12 through a furnace at a high temperature for a short amount of time. For example, the process may pass the substrate 12 through a furnace at 850 degrees C. for approximately 1 second. This short but quick heating effectively solidifies the conductive paste, and causes the conductive paste to “fire through” the antireflective coating. In other words, the conductive paste penetrates through the antireflective coating to make ohmic contact with the substrate 12. Accordingly, the fingers 18 and discontinuous busbars 20 contact the substrate 12 in a manner that causes their respective current-voltage curves to be substantially linear. In other embodiments, the discontinuous busbars 20 are not in ohmic contact with the substrate 12.

Also of significance is the fact that the insulative qualities of the antireflective coating prevent a direct electrical connection between two adjacent pads 32 across the top face 14A (i.e., without the fingers 18, 18P or tabs 22 configured as discussed, there is no electrical connection). Of course, as noted above, adjacent pads 32 may have some electrical connection through the substrate 12, but such a connection is not the type of direct electrical connection provided by a wire, tab 22, or other direct electrical path.

The process then continues to step 1112, which secures the tabs 22 to the discontinuous busbars 20. To that end, conventional processes first may screen-print solder onto each of the pads 32, and then use a hotplate to melt the solder. At this stage, each pad 32 of a discontinuous busbar 20 has a solder ball for receiving a tab 22. A scaffolding holding a row of tabs 22 under tension thus is moved downwardly to contact each solder ball with a tab 22. The solder balls then cool, consequently securing the tabs 22 to the pads 32. One advantage of using solder balls in this process is their ability to connect securely with the tabs 22 despite irregularities in the contour of the pads 32 and substrate 12.

It should be noted that the tabs 22 electrically connect indirectly with the substrate 12 via the pads 32 only. The insulative antireflective coating/layer prevents the tabs 22 from directly electrically connecting with the substrate 12 through any other portion of the top face 14A of the substrate 12.

The process concludes at step 1114 by affixing the metal strip 24 (see FIG. 2A) to the tabs 22. Any conventional means for making this connection should suffice, such as conventional soldering techniques.

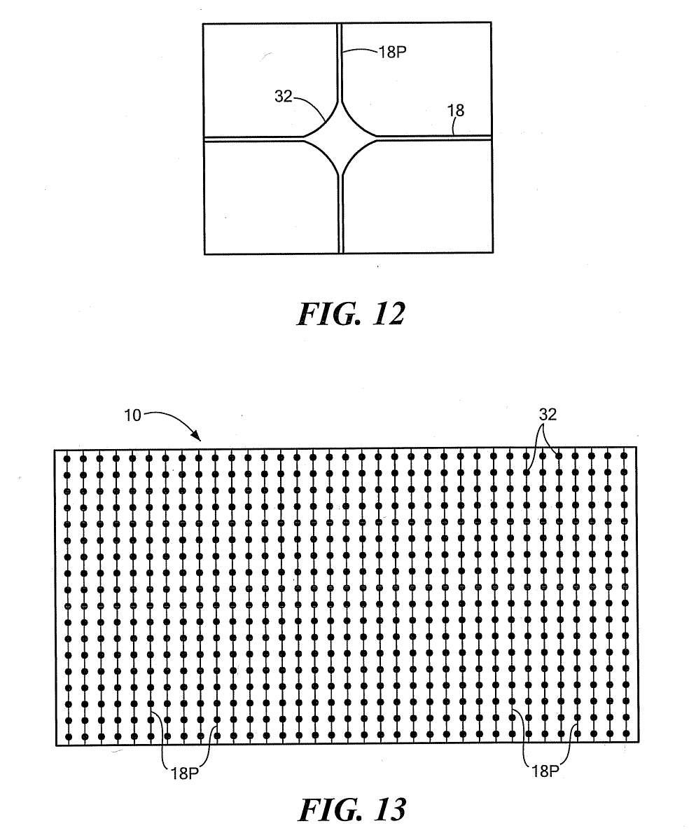

FIG. 13 schematically shows another embodiment of the invention in which the top face 14A of the substrate has substantially no exposed fingers 18 or 18P. In this case, the pad fingers 18P (exposed with tabs 22 removed as in other figures) both 1) gather carriers, and 2) beneficially transmit carriers to an adjacent pad 32 in the same discontinuous busbar 20 in the event of a bond break between a pad 32 and a tab 22. In addition, this embodiment has less coverage of its top face 14A, thus permitting more light to energize its carriers.

Of course, in other embodiments, the pad fingers also collect some of the charge carriers (as well as the other fingers 18 on the cell 10). Accordingly, the pad fingers in those embodiments also should provide some additional efficiency boost to the extent that they collect the charge carriers.

Although the above discussion discloses various exemplary embodiments of the invention, it should be apparent that those skilled in the art can make various modifications that will achieve some of the advantages of the invention without departing from the true scope of the invention.

What is claimed is:

1. A photovoltaic cell comprising:
a photosensitive substrate;
a plurality of fingers in ohmic contact with the substrate;
a plurality of pads on the substrate, the plurality of pads forming a plurality of discontinuous busbars,
two of the fingers extending from a first pad of the plurality of pads, a given one of the two fingers connecting with a second pad of the plurality of pads, the first pad and second pad being part of the same given busbar, the given finger having an inter-pad portion between the first and second pads; and
a tab connected with at least a portion of the given busbar and covering at least part of the inter-pad portion of the given finger.

2. The photovoltaic cell as defined by claim 1 wherein the two fingers comprise a first finger and the given finger, the first finger being generally orthogonal to the given finger.

3. The photovoltaic cell as defined by claim 2 wherein the first finger also connects to a third pad, the portion of the first finger extending from the pads being substantially uncovered.

4. The photovoltaic cell as defined by claim 1 wherein the tab substantially entirely covers the inter-pad portion of the given finger.

5. The photovoltaic cell as defined by claim 1 wherein the plurality of fingers comprise discontinuous fingers.

6. The photovoltaic cell as defined by claim 1 wherein the plurality of fingers comprise substantially continuous fingers.

7. The photovoltaic cell as defined by claim 1 wherein the given finger connects with a third pad of the given busbar, the tab covering at least a part of the given finger adjacent to the third pad.

8. The photovoltaic cell as defined by claim 1 wherein the plurality of pads are arranged in a two dimensional array, the given busbar having a plurality of additional pads, the given finger electrically connecting with the additional pads in the given busbar.

9. The photovoltaic cell as defined by claim 8 wherein the two-dimensional array forms a plurality of additional busbars that are generally parallel with the given busbar, the cell further comprising a plurality of additional tabs, each additional busbar being connected to one of the additional tabs.

10. The photovoltaic cell as defined by claim 9 wherein each additional busbar comprises multiple pads, each busbar connecting with at least one finger for connecting at least two of its multiple pads.

11. The photovoltaic cell as defined by claim 1 wherein the plurality of pads comprises a plurality of pads that each have at least four concavities.

12. The photovoltaic cell as defined by claim 1 wherein the two fingers comprise a first finger and the given finger having substantially the same thicknesses.

13. The photovoltaic cell as defined by claim 1 wherein the two fingers comprise a first finger and the given finger, the first finger being not parallel with the given finger.

14. A method of forming a photovoltaic apparatus, the method comprising:
providing a photosensitive substrate;
forming a plurality of pads on the substrate, the plurality of pads forming a plurality of discontinuous busbars,
forming a first set of first fingers and a given set of given fingers, each given finger physically and electrically connecting with at least two of the pads in a single busbar, each of the at least two pads also being connected with at least one first finger; and
securing a plurality of tabs to the plurality of busbars so that each busbar is secured to a tab, each tab covering at least a portion of the given fingers between pads.

15. The method as defined by claim 14 wherein the pads, first set and given set of fingers are formed at least in part using a screen printing process.

16. The method as defined by claim 15 wherein the pads and fingers are formed at substantially the same time.

17. The method as defined by claim 14 wherein forming a plurality of pads comprises:
depositing material on the substrate through a template, the template defining the first fingers and the given fingers, and
removing the template after depositing the material to form the first and given fingers, the first fingers intersecting the given fingers to form the plurality of pads.

18. The method as defined by claim 17 wherein the plurality of pads includes a set of pads shaped with four concavities.

19. The method as defined by claim 14 wherein each of the tabs substantially entirely covers the portion of the given fingers between pads, at least one of the tabs leaving at least one pad uncovered.

20. The method as defined by claim 14 further comprising:
connecting the substrate with a plurality of additional substrates to form a photovoltaic panel.

21. The method as defined by claim 14 wherein the plurality of pads form a two dimensional array on the substrate.

22. The method as defined by claim 14 wherein the first fingers are not parallel with the given fingers.

23. A photovoltaic cell comprising:
a photosensitive substrate having a top surface;
a plurality of fingers in ohmic contact with the top surface of the substrate;
a plurality of pads in ohmic contact with the plurality of fingers, the plurality of pads forming a plurality of discontinuous busbars; and
a plurality of tabs secured to at least portions of the busbars, the plurality of tabs substantially entirely covering the plurality of fingers, the top surface of the substrate being substantially free of uncovered fingers.

24. The photovoltaic cell as defined by claim 23 wherein the plurality of tabs do not entirely cover the plurality of pads.

25. The photovoltaic cell as defined by claim 23 wherein the each of the plurality of fingers is generally coplanar with one of the busbars.

26. The photovoltaic cell as defined by claim 23 wherein the plurality of fingers comprises a plurality of substantially continuous fingers.

27. The photovoltaic cell as defined by claim 23 wherein the plurality of fingers comprises a plurality of substantially discontinuous fingers.

28. The photovoltaic cell as defined by claim 23 wherein the plurality of pads comprises a two-dimensional array of pads across the substrate.

29. The photovoltaic cell as defined by claim 23 wherein the plurality of pads comprises a plurality of pads that each have at least four concavities.
